(19) United States
(12) Patent Application Publication
(10) Pub. No.: US 2009/0080584 A1
(43) Pub. Date: Mar. 26, 2009

(54) SEMICONDUCTOR SYSTEM

(75) Inventors: Daisuke HAMANO, Hachioji (JP); Keiki WATANABE, Tachikawa (JP)

Correspondence Address: MILES & STOCKBRIDGE PC, 1751 PINNACLE DRIVE, SUITE 500, MCLEAN, VA, 22102-3833, US

(73) Assignee: HITACHI, LTD.

(21) Appl. No.: 12/172,543

(22) Filed: Jul. 14, 2008

(30) Foreign Application Priority Data
Sep. 21, 2007 (JP) 2007-244641

(51) Int. Cl. H04L 7/00; H03M 9/00

(52) U.S. Cl. 375/371; 341/101

(57) ABSTRACT

A semiconductor system has a SerDes circuit for receiving serial data, and a reference SerDes circuit for receiving clock signals running in parallel. The SerDes circuit performs serial to parallel conversion of the serial data captured by the recovery clock whose phase is controlled by utilizing the phase control signal P_CS generated by the reference SerDes circuit.

### CLAIM OF PRIORITY

The present application claims priority from Japanese patent application JP 2007-244641 filed on Sep. 21, 2007, the content of which is hereby incorporated by reference into this application.

### FIELD OF THE INVENTION

The present invention relates to a semiconductor system and relates in particular to a clock data recovery (CDR) circuit for reproducing clock signals from received data used in high-speed data transfer between devices.

### BACKGROUND OF THE INVENTION

In order to attain high-speed data transmission between semiconductor systems, serial transmission has become widely used in recent years to transfer data between semiconductor systems. Semiconductor systems utilizing this type of serial transmission, utilize a SerDes (Serializer and Deserializer) circuit to convert the parallel data for transmission to serial data, and convert the received serial data to parallel data. In the typically used method, the SerDes circuit of the transmitter semiconductor system sends the serialized data which is synchronized with a transmission path clock along the transmission path to the receiver semiconductor system; the SerDes circuit in the receiver semiconductor system then extracts the clock from the received serial data and converts the received serial data to the parallel data. The circuit for extracting the clock from the received serial data is called the CDR circuit. For transmitting large amounts of the high-speed serial data, the semiconductor system possesses transmission paths on multiple channels and a SerDes circuit for each channel.

The structure of a typical clock and data recovery circuit for this type of SerDes circuit is disclosed in JP-A No. 2007-184847.

### SUMMARY OF THE INVENTION

Demands have increased in recent years for high-speed serial data transmission in the several Giga bps class, and a CDR circuit with a sophisticated follow-up (slaving) ability is needed.

FIG. 2 shows a transmission method evaluated by the inventor prior to this patent application. A semiconductor system 201 includes a CDR circuit 1, a parallel to serial converter 2, a serial to parallel converter 3, an input buffer 4, an output buffer 5, and a clock buffer 6; and in particular contains clocks running in parallel that are allotted one to each CDR circuit 1. In the transmission method in FIG. 2, this serial data is received by finding the phase differential between the received data and the clock obtained by phase interpolation of the clock running in parallel (hereafter called parallel clock) using the CDR circuit 1. However, achieving a stable transfer rate in the Giga class used in recent years is difficult due to jitter and noise in the output buffer 5, transmission path 8, input buffer 4 and the clock buffer 6. The CDR circuit 1 analyzes the phase differential based on a parallel clock with poor signal quality, so that the jitter component in the parallel clock directly affects the CDR circuit 1 performance. High accuracy skew alignment and duty alignment are required if parallel clocks running at a high frequency are allotted to the multiple CDR circuits 1. Moreover, the CDR circuit 1 must align the clock phase by itself, so that the accuracy when slaving the phase to the received data deteriorates if the receive data contains consecutive identical code characters.

The present inventors next evaluated a transmission method as shown in FIG. 3 for allotting output signals from the PLL circuit 7 using the parallel clock as a reference signal, to each CDR circuit 1, rather than allotting the parallel clock unchanged, to each CDR circuit 1. In the transmission method as shown in FIG. 3, even though the PLL clock 7 receives the parallel clock, the parallel clock whose signal quality has deteriorated due to jitter and noise in the output buffer 5, the transmission path and the input buffer 4, is utilized as a reference signal for PLL circuit 7, so that the signal quality in the output signal from PLL circuit 7 also deteriorates. The receive performance consequently deteriorates the same as in the circuit scheme in FIG. 2. The CDR circuit 1 must control the clock phase by itself, so that the phase follow-up (slaving) is inadequate when there are consecutive identical code characters in the received data.

The present inventors therefore perceived that in order to achieve stable high-speed serial data transfer in send/receive systems made up of multiple SerDes circuits (CDR circuits) some measure was still needed to suppress effects from jitter and noise on the CDR circuit even if using parallel clocks. Moreover, the present inventors also perceived that a deterioration in CDR circuit follow-up performance must be avoided when consecutive identical characters are used in the received data.

A simple description of a typical aspect representative of the invention the disclosed in this application is given next. A semiconductor system includes a first clock and data recovery circuit for receiving first serial data from a first transmission path, a second clock and data recovery circuit for receiving second serial data from a second transmission path, and a first serial to parallel converter circuit for converting the first serial data to parallel data using the recovery clock from the first clock and data recovery circuit; and the first clock and data recovery circuit controls the phase of the recovery clock with any of the signals from the second phase control signal generated by the second clock and data recovery circuit or a first phase control signal generated by the first clock and data recovery circuit.

This semiconductor system achieves highly accurate, high-speed transmission of serial data. Serial data transfer is also stable even when the serial data received at high speed contains consecutive identical code characters. Moreover, electrical power consumption is lowered in the overall system.

### BRIEF DESCRIPTION OF THE DRAWINGS

FIG. 1 is a block diagram of the semiconductor system of this invention;

FIG. 2 is a block diagram of the semiconductor system evaluated for this invention;

FIG. 3 is a block diagram of the semiconductor system evaluated for this invention;

FIG. 4 is a block diagram showing the main structure of the SerDes circuit 101;

FIG. 5 is a block diagram showing in detail the CDR circuit 402;

FIG. 6 is a block diagram showing in detail the phase detector 501 of the CDR circuit 402;

FIG. 7A is a drawing showing the operation of the lowest weighted shift register in the average circuit 502 of CDR circuit 402;

FIG. 7B is drawing showing the carry operation among the shift registers; FIG. 7C is a concept drawing showing the structure of the average circuit 502 made up of multiple shift registers of different weights;

FIG. 8 is a block diagram showing in detail the compare circuit 503 of CDR circuit 402;

FIG. 9 is a block diagram showing in detail the mode select circuit 504 of CDR circuit 402;

FIG. 10A is a block diagram showing in detail the clock control circuit 505 of CDR circuit 402;

FIG. 10B is a drawing showing the relation between the four types of signals (SELIP, SELQP, SELIN, SELQN) and the phase information held in the two-way shift register 1001;

FIG. 10C is a drawing showing the relation between the four types of signals (SELIP, SELQP, SELIN, SELQN) and each clock phase when using 16 matching phases; and

FIG. 11 is a circuit diagram showing in detail the clock generation circuit 506 of CDR circuit 402.

### DETAILED DESCRIPTION OF THE PREFERRED EMBODIMENTS

The embodiment of the invention is hereafter described in detail.

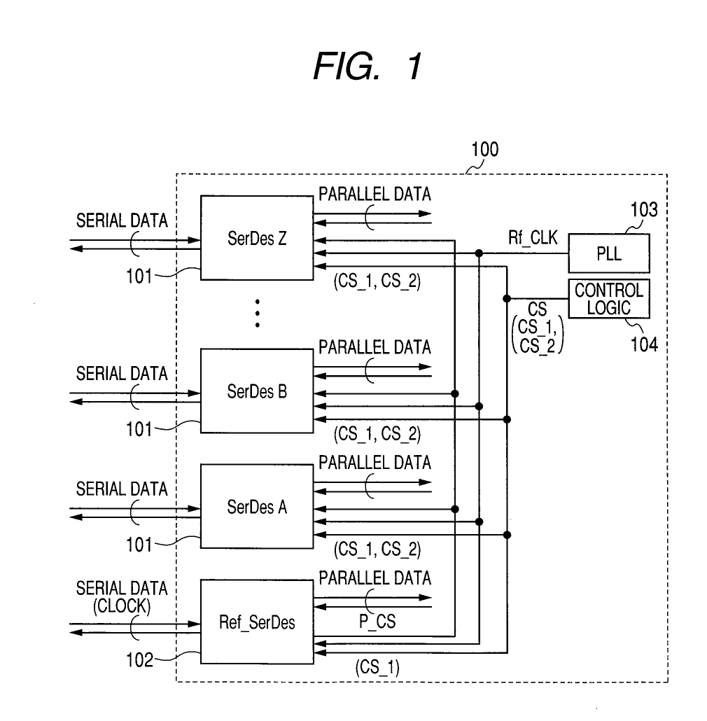

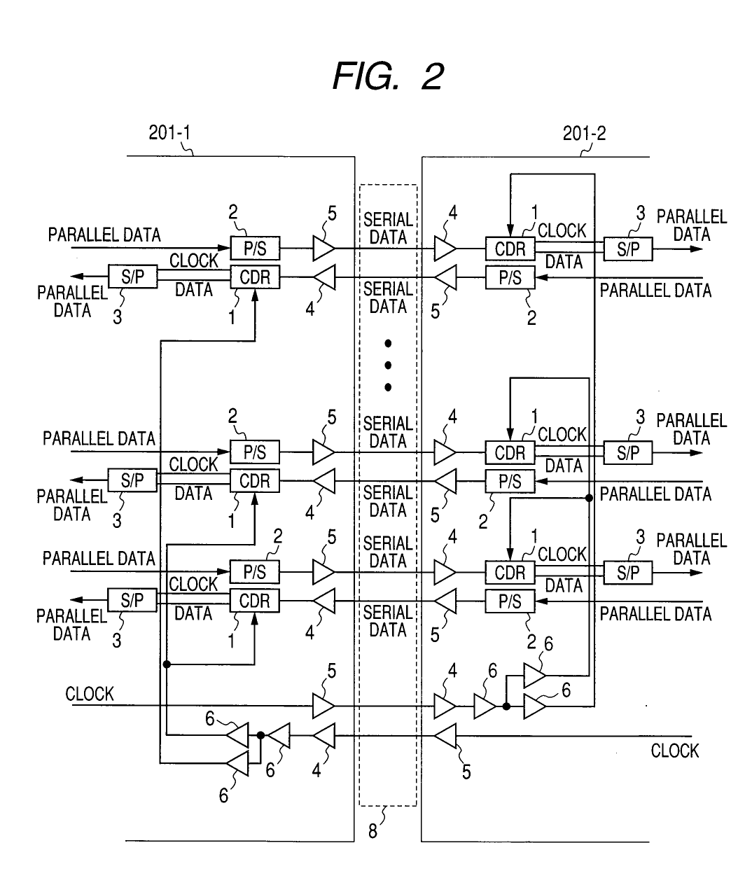

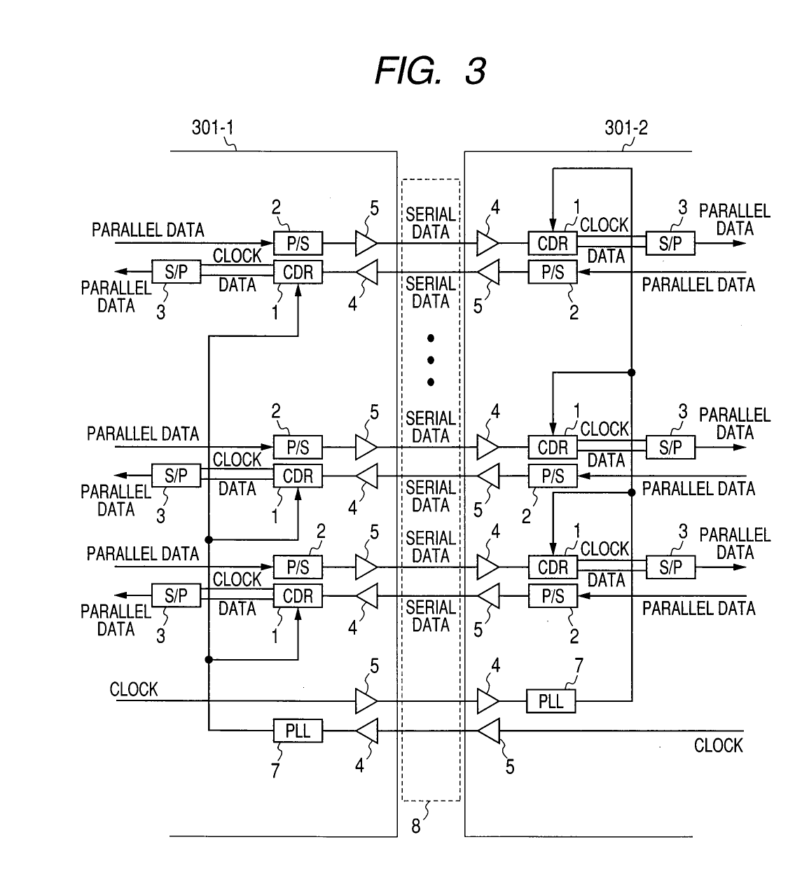

As shown in FIG. 1, a semiconductor device 100 of this embodiment contains multiple SerDes circuits 101. Each of these multiple SerDes circuits 101 receives parallel data from an internal circuit (not shown in drawing), converts the parallel data to serial data, and output it along the transmission path. These multiple SerDes circuits 101 also receive the serial data from the transmission path, convert the serial data to parallel data, and output it to an internal circuit. Moreover, the semiconductor device 100 includes a reference SerDes circuit 102 to accept the parallel clock as serial data. This reference SerDes circuit supplies phase control signals P_CS to each of the SerDes circuits 101. A PLL circuit 103 supplies reference clocks Rf_CLK to each SerDes circuit 101 and reference SerDes circuit 102. The control logic 104 supplies control signals CS to the SerDes circuits 101.

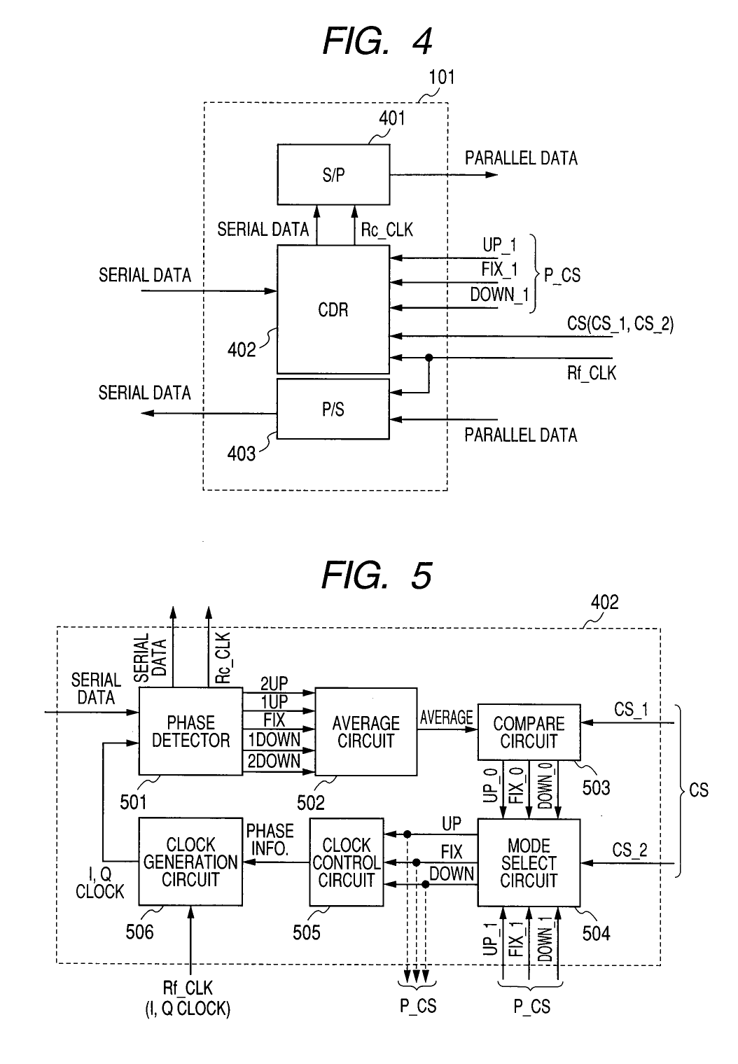

The SerDes circuit 101 and the reference SerDes circuit 102 possess the same structure, so a description is related using the drawings for the SerDes circuit 101 structure, and the differing points on the reference SerDes circuit 102 are described where necessary. FIG. 4 shows the main structural elements of the SerDes circuit 101. The SerDes circuit 101 includes a serial to parallel converter 401 for converting serial data to parallel data, a parallel to serial converter 403 for converting parallel data to serial data, and a clock and data recovery circuit (hereafter CDR circuit) 402. A phase control signal P_CS sets any of the UP/FIX/DOWN states. The phase differential information is from hereon labeled UP_1/FIX_1/DOWN_1 based on this phase control signal P_CS. The reference SerDes circuit 102 does not accept this phase control signal P_CS.

The serial to parallel converter 401 captures the serial data using the recovery clock Rc_CLK on the CDR circuit 402, and converts it to the parallel data. The serial to parallel converter 401 utilizes a typical structure, so a detailed description is omitted. The parallel to serial converter 403 converts the transmit data in parallel format to serial data. The parallel to serial converter 403 utilizes a typical structure, so a detailed description is omitted.

The CDR circuit 402 as shown in FIG. 5 includes a phase detector 501, an average circuit 502, a compare circuit 503, a mode select circuit 504, a clock control circuit 505, and a clock generation circuit 506. Serial data captured by the phase detector 501 is input to the serial to parallel converter 401.

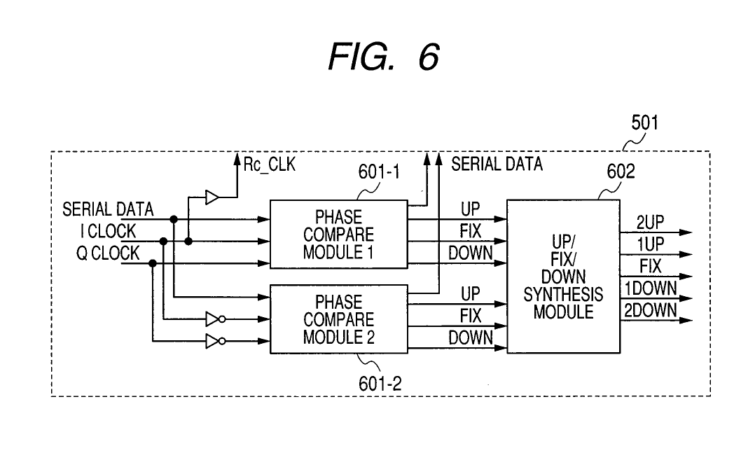

The phase detector 501 shown in FIG. 6 is a structure for a phase detector that uses the so-called half-rate method. The phase detector 501 compares the phases by using a clock whose frequency is a half of the received serial data rate. The input clocks are of two types, an I-clock and a Q-clock having a mutual phase difference of π/2. A phase compare module 601-1 operates using the positive edges of the I-clock and Q-clock pulses. The phase compare module 601-2 on the other hand, operates using the negative edge of the I-clock and Q-clock via input of inverted I-clock and inverted Q-clock. The phase compare module 601 outputs: a phase delay signal (UP signal) showing that the clock phase is delayed (lagging) compared to the serial data, a phase clamping signal (FIX signal) showing that the deviation between the phase of the clock and the phase of the serial data is within a specified range, and a phase lead (DOWN signal) signal showing that the clock phase is leading compared to the phase of the serial data. The phase differential information output from the two phase compare modules 601 are synthesis in the UP/FIX/DOWN synthesis module 602. This UP/FIX/DOWN synthesis module 602 outputs five types of signals (2UP/1UP/FIX/1DOWN/2DOWN) by utilizing combinations of UP, FIX and DOWN signals from the two phase compare modules 601. This UP/FIX/DOWN synthesis module 602 can be constructed like addition of the phase differential information of the phase compare modules 601-1 and the phase differential information of the phase compare modules 601-2. In that case, if an “UP(DOWN)” and “UP(DOWN)” are obtained from the two phase compare modules 601 then the UP/FIX/DOWN synthesis module 602 outputs a “2UP(2DOWN)”. Likewise if an “UP(DOWN)” and “FIX” are obtained then a “1UP(1DOWN)” is output; and if an “UP(DOWN)” and “DOWN(UP)”, or “FIX” and “FIX” are obtained then the UP/FIX/DOWN synthesis module 602 outputs a “FIX”.

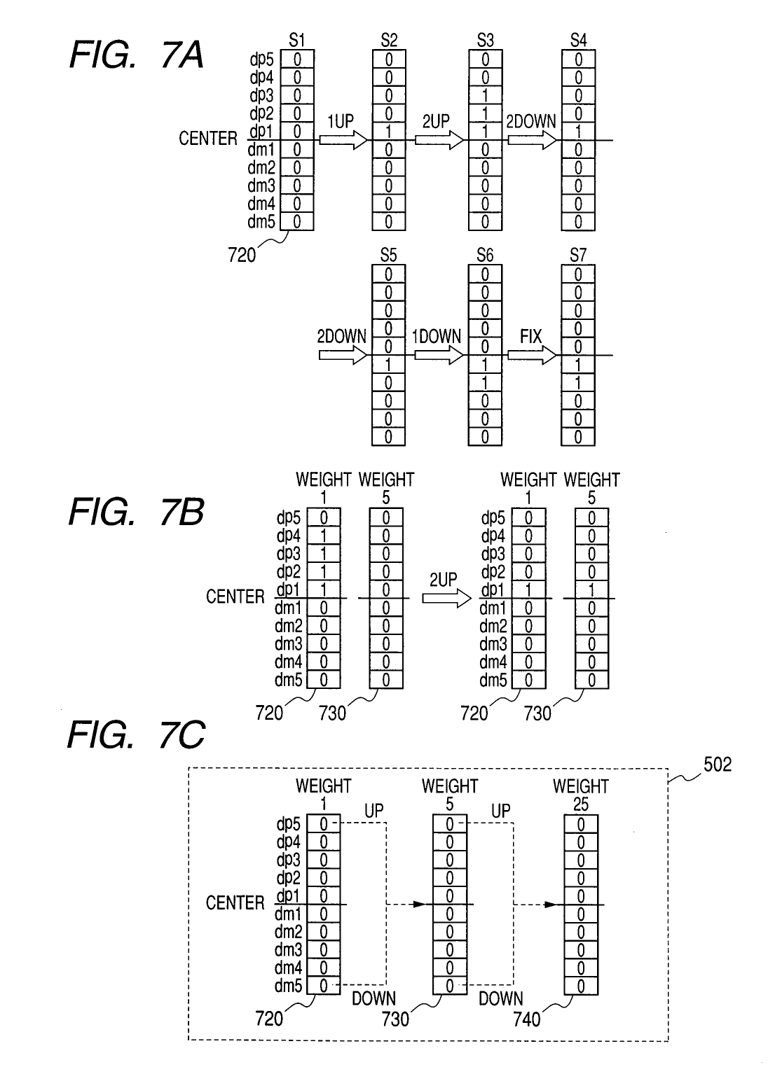

The average circuit 502 receives the output from the phase detector 501. The average circuit 502 calculates the time average of phase differential information supplied from the phase detector 501. The operation of the shift registers making up the average circuit 502 is described using FIG. 7A through FIG. 7C.

The example in the average circuit of this embodiment as shown in FIG. 7C utilizes shift registers that add in quinary (base 5). The shift register 720 is weighted 5° (=1), the shift register 730 is weighted 5¹ (=5), and the shift register 740 is weighted 5² (=25). A logic value of 0 is input to each register while in the initialized state.

A signal input from the phase detector 501 changes the logic value held in each register. FIG. 7A shows the operation of the shift register 702 that is weighted 1. The shift register 720 contains the registers dp 1-5 in sequence from the center upward, and the registers dm 1-5 in sequence from the center downward. The shift register operation is defined as follows.

(1) When all registers are at a logic value of 0, a 1 is input to register dp1 when an “1UP signal” is input; and a 1 is input to the register dm1 when a “1DOWN signal” is input.
(2) When the register at the highest position in the shift register 720 at a logic value 1 is the register dp (in other words, the register on the upper side from center), and a “1UP signal” is input then a 1 is input to the next highest register, and when a “1DOWN signal” is input then a 1 is subtracted from that register.
(3) When the register at the lowest position in the shift register 720 at a logic value 1 is the register dm (in other words, the register on the lower side from center), and a “1UP signal” is input then a 1 is subtracted from that register, and when a “1DOWN signal” is input then a 1 is input to the next lowest register.
(4) The “FIX signal” does not change the state of the shift register. Moreover, the “2UP signal” “2DOWN signal” are each equivalent to two “UP signals” and “DOWN signals”.

In the example in FIG. 7A, a “1UP” “2UP” “2DOWN” “2DOWN” “1DOWN” “FIX” signal are shown input in sequence. When a “1UP” signal is input to the shift register in the initial state (S1), the register dp1 is held to a logic value 1 (S2). Next, when a “2UP” signal is input, the registers dp2, dp3 are held to a logic value 1 (S3). Next, when a “2DOWN” signal is input, the logic value in the registers dp2, dp3 is subtracted, and only the register dp1 is held to a logic value 1 (S4). When a “2DOWN” signal is next input, along with subtracting the register dp1 logic value, the register dm1 is held at a logic value 1 (S5). Next, when a “1DOWN” signal is input, the register dm2 is also held at a logic value 1 (S6). When the “FIX” signal is next input, the register maintains the same logic value unchanged (S7).

The carry operation is described next using FIG. 7B. When a “1UP” signal is input while the registers dp1-dp4 of the shift register 720 are held at a logic value 1, then an overflow signal dp5 is output and the shift register 720 returns to the initial state. An overflow signal dp5 is also input to the shift register 730. Moreover, when a “1DOWN” signal is input while the registers dm1-dm4 of the shift register 720 are held at a logic value 1, then an overflow signal dm5 is output and the shift register 720 returns to the initial state. Moreover an overflow signal dm5 is input to the shift register 730. Operation of the shift register 730 is the same as the shift register 720; and the “1UP” signal in the shift register 720 may be read as the “OVERFLOW signal dp5”; and the “1DOWN” signal in the shift register 720 may be read as the “OVERFLOW signal dm5”. Shift registers weighted 5ⁿ are also the same, operating based on the “OVERFLOW signal dm5” and the “OVERFLOW signal dp5” of weighted 5⁽ⁿ⁻¹⁾ shift register. In the example in FIG. 7B, a “2UP” signal in input, and the register dp1 weighted to 1 is held at a logic value 1, and register dp1 weighted to 5 is held at a logic value 1.

The shift register used in the embodiment described above has many UP signal counts when the center to upper side of the register is at a logic value 1. Conversely, there are many DOWN signal counts when the center to lower side of the register is at a logic value 1. A logic value 0 at all registers indicates that the DOWN signals match the UP signal count.

Compared to simply expanding the width of a single shift register, this structure allows performing the same averaging with a small number of registers because the signals processed in the shift register are weighted differently. This scheme also reduces the required circuit scale. Moreover only low-weighted shift registers need be operated at a high frequency, so the power consumption can be lowered in the overall system. Another feature is an effect that suppresses a phenomenon, caused by using the conventional overflow algorithm, that the clock phase is slaved to local fluctuations in the phase differential information and consequently improves the CDR circuit 402 performance. The averaging in this embodiment was achieved by addition in quinary (base 5) in the shift register but is not limited to this example and may be adapted to other bases.

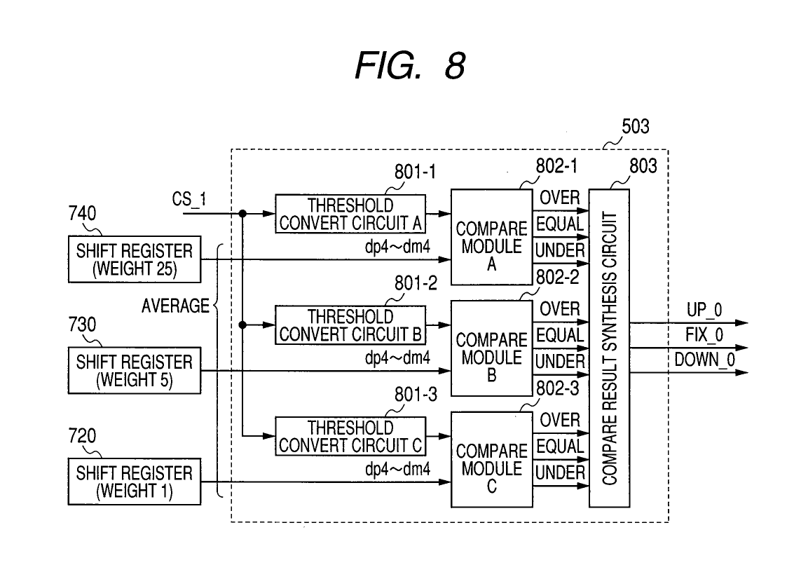

As shown in FIG. 8, the compare circuit 503 of CDR circuit 402 includes the compare modules 802-1 through 802-3 for comparing the threshold levels in each of the differently weighted shift registers; a compare result synthesis circuit 803 for gathering the comparison results and generating an UP signal, a FIX signal, or a DOWN signal to change the clock phase; and the threshold convert circuits 801-1 through 801-3 for converting the threshold levels to match the shift register base notation to allow comparing the control signal CS_1 expressing the threshold levels supplied from the control logic 104, with the values held in the differently weighted shift registers 720, 730, 740. The threshold levels include two values that are a positive threshold level and a negative threshold level. The compare modules 802 compare the shift register count (dp4 through dm4) with the threshold level converted by the threshold convert circuit 801 and: output an “over” if the count is a positive value and is also larger than the threshold level; output an “under” if the count is a negative value and is also smaller than the threshold level; and output an “equal” if other none of the above values. The compare result synthesis circuit 803 weights the output signals from the compare modules 802-1 through 802-3 due to the shift register weighting, and compares the threshold levels with the overall count for all shift registers. In this embodiment, the compare result synthesis circuit 803 generates an UP signal if the compare module 802-1 for large-weighted shift registers outputs “over”; generates a DOWN signal if the compare module 802-1 outputs “under”; and searches the results from the compare module 802-2 if the compare module 802-1 outputs “equal”. The compare result synthesis circuit 803 generates an UP signal if the compare module 802-2 outputs “over”; generates a DOWN signal if the compare module 802-2 outputs “under”; and searches the results from the compare module 802-3 for further smaller-weighted shift registers if the compare module 802-2 outputs “equal”. The compare result synthesis circuit 803 generates an UP signal if the compare module 802-3 outputs “over”; generates a DOWN signal if the compare module 802-3 outputs “under”; and generates a FIX signal if the compare module 802-3 outputs “equal”. The register values (dp4-dm4) for each shift register are in this way compared in parallel with the threshold level. This method is realized by combining differently-weighted shift registers to an averaging process and is extremely superior in terms of high-speed operation to conventional methods utilizing adder/subtractor circuits.

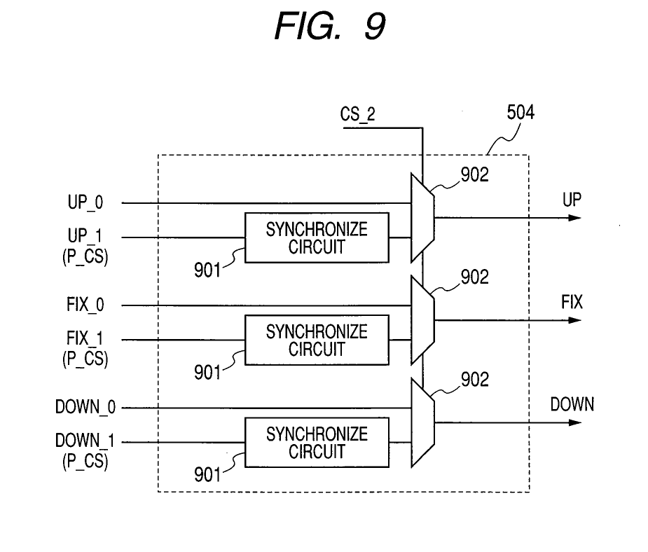

The mode select circuit 504 of CDR circuit 402 includes the selector circuits 902 and the synchronize circuits 901 as shown in FIG. 9. The mode select circuit 504 selects either the clock phase control signal UP/FIX/DOWN signal (expressed as UP_0/FIX_0/DOWN_0) yielded autonomously by the CDR circuit 402; or the UP/FIX/DOWN signal (UP_1/FIX_1/DOWN_1) supplied as the phase control signal P_CS yielded autonomously by the CDR circuit 402 of the reference SerDes circuit 102, and inputs it to the clock control circuit 505 in a latter stage. The control signal CS_2 generated by the control logic 104 is utilized to decide which signal to select.

Functions implemented by the mode select circuit 504 are described next. Frequent changing of the data values in the received data input to the CDR circuit 402 usually generates data edges. The CDR circuit 402 adjusts the phase of the clock by finding the phase difference between the clock edges and these data edges. However a data ge cannot be formed if the received data contains identical consecutive characters, so making an effective phase comparison with the clock is impossible. In other words, the phase of the clock Rc_CLK output by the CDR circuit 402 cannot be accurately controlled for identical consecutive character data. The SerDes circuit 101 might therefore be unable to accurately receive serial data if the data characters are inverted following the identical consecutive characters. In order to prevent this problem, the data whose edge frequently changes, for example clock signal, is employed in the received data for one of the multiple SerDes circuits (reference SerDes circuits 102) to generate the valid phase differential information, and consequently an UP/FIX/DOWN signal (phase control signal P_CS) for controlling the clock is yielded. Signals received by the reference SerDes circuit 102 are therefore not limited to clock signals that change periodically and may also be signals whose values change randomly such as signals where the data characters invert more frequently than the normal data. The SerDes circuit 101 therefore prevents a drop in clock phase control accuracy due to fewer edges n the received data, by controlling the clock phase utilizing two signals. One signal is the UP/FIX/DOWN signal (UP_0/FIX_0/DOWN_0) yielded autonomously by each SerDes circuit 101 and the other is the UP/FIX/DOWN signal (UP_1/FIX_1/DOWN_1) yielded autonomously by the reference SerDes circuit 102.

Other characteristics of the CDR circuit 402 used in the mode select circuit 504 are described next. During the initializing stage (training period) of the device, each SerDes circuit 101 generates a state synchronous with the received data, then the clock Rc_CLK phase of CDR circuit 402 is controlled by the phase control signal P_CS from the reference SerDes circuit 102. This sequence cancels out variations in the received data timing occurring due to factors such as the transmission path, as well as variations in the CDR circuit 402 of each SerDes circuit 101. The selection (switching) sequence is not limited to the above described sequence, and the switching to either the autonomously obtained phase control signal (UP_0/FIX_0/DOWN_0) or the phase control signal P_CS from the reference SerDes circuit 102 may be decided based on the error rate of the SerDes circuit. Moreover, after switching to the phase control signal P_CS from the reference SerDes circuit 102, a high receive accuracy can be maintained and the power consumption of the overall system can be reduced by stopping the circuit used for autonomous phase control among the CDR circuits 402 in SerDes circuit 101.

Externally supplied phase control signals can be applied as inputs to the mode select circuit 504. These external signals allow controlling the phase of the clock Rc_CLK in CDR circuit 402. External signals of any type may be input to the mode select circuit 504 provided the circuit scale and operating speed is acceptable. Besides the reference SerDes circuit 102, the phase of the clock Rc_CLK of CDR circuit 402 may be controlled from the upstream logic for uses other than normal operation such as evaluating the CDR circuit 402 performance.

The reference SerDes circuit 102 does not require a mode select function for switching modes, however the SerDes circuit 101 may be jointly utilized if making a fixed selection of the autonomously obtained phase control signal (UP_0/FIX_0/DOWN_0). Moreover in the reference SerDes circuit 102 as shown by the dotted line in FIG. 5, the phase control signal P_CS must be output as the phase control signal (UP/FIX/DOWN). However, in this case also a circuit can be jointly used so that there is no output from the SerDes circuit 101.

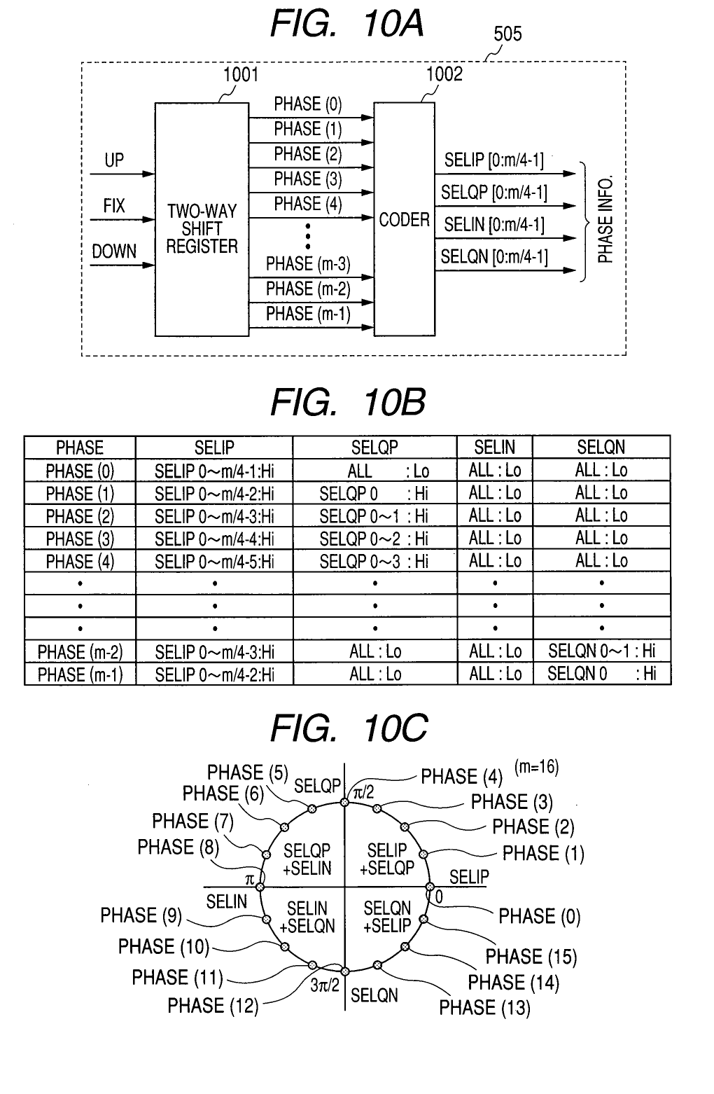

As shown in FIG. 10A, the clock control circuit 505 in the CDR circuit 402 usually contains a two-way shift register 1001, and a coder 1002 for converting to a signal format suitable for input the clock generation circuit 506 in a latter stage. The clock control circuit 505 holds the phase of the clock applied to the phase detector 501, and holds or changes the phase according to the UP signal, FIX signal and DOWN signal input from the mode select circuit 504 in a previous stage. In the example in FIG. 10A, the phase number m is used to control the phase. In this example, the two-way shift register 1001 holds or changes the clock phase. However this invention is not limited to the above example and usage of other structures is not a problem along as the structure is capable of holding or changing the phase.

As shown in FIG. 10B, the coder 1002 expresses the phase information for m items (phase (0) through phase (m−1)) acquired from the two-way shift register 1001 in the previous stage, by using two from among the four types of signals (SELIP, SELQP, SELIN, SELQN). This scheme serves to reduce the electrical power and the circuit scale. An example where the phase number m equals 16 is shown in FIG. 10C. In this case, if each phase is expressed as SELIP[0:3(16/4-1)], SELQP[0:3], SELIN[0:3], SELQN[0:3], then phase (0) through phase (3) are expressed by a combination of SELIP[0:3] and SELQP[0:3]; phase (4) through phase (7) are expressed by a combination of SELQP [0:3] and SELIN[0:3]; phase (8) through phase (11) are expressed by a combination of SELIN[0:3] and SELQN[0:3]; and phase (12) through phase (15) are expressed by a combination of SELQN[0:3] and SELIP[0:3]. As shown in FIG. 10B at phase (0), SELIP[0-3] are all Hi (level) and SELQP[0:3], SELIN[0:3], SELQN[0:3] are all Lo (level). Also, in phase (1), SELIP[0-2] transitions to Hi, and SELIP[3] transitions to Lo. SELQP[0] transitions to Hi, and SELQP[1:3] remains Lo. The SELIN[0:3] and SELQN[0:3] all transition to Lo.

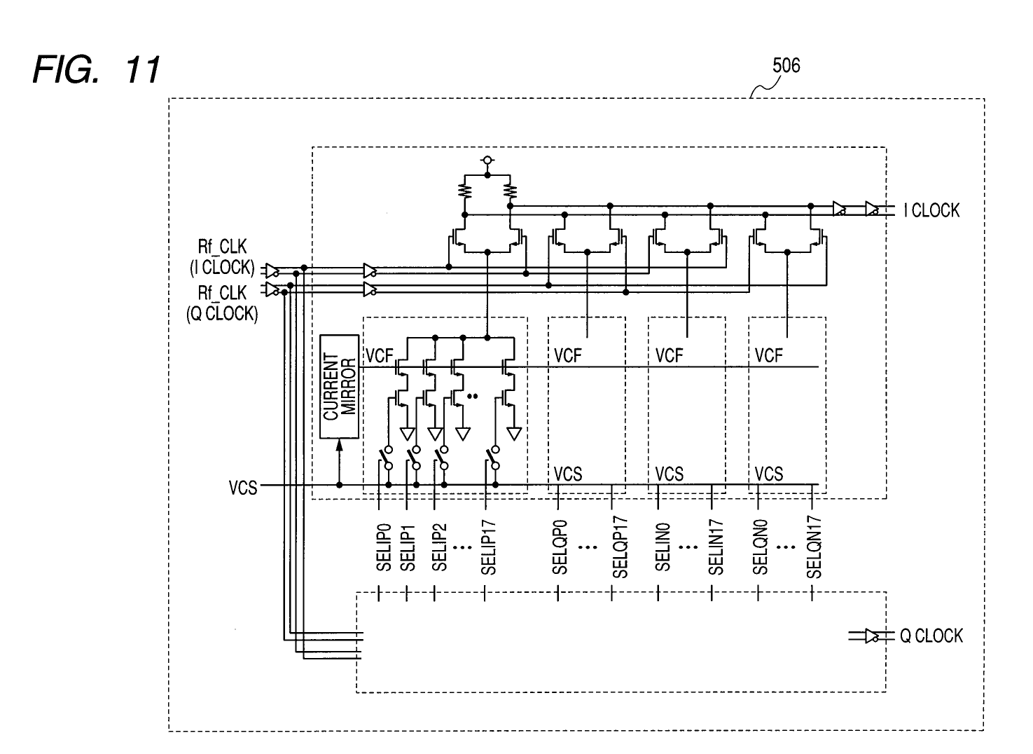

The clock generation circuit 506 of CDR circuit 402 as shown in FIG. 11, generates the recovery clock according to infinitesimal phase deviation by controlling the current which is adjusted by the output signals (SELIP, SELQP, SELIN, SELQN) from the clock control circuit 505 in a previous stage. The input signal to the clock generation circuit 506 in FIG. 11 corresponds to an m equaling 72 in FIG. 10. The I-clock and a Q-clock whose phases are controlled by the clock generation circuit 506, are input to the phase detector 501, and then the phase of these clocks is compared with the phase of the received serial data.

This invention is no way limited by the above embodiment and changes and adaptations not departing from the spirit and scope of the invention are permitted.

What is claimed is:

1. A semiconductor system comprising:
a first clock and data recovery circuit for receiving first serial data from a first transmission path;
a second clock and data recovery circuit for receiving second serial data from a second transmission path;
a first serial to parallel converter circuit for converting the first serial data to parallel data by using the recovery clock from the first clock and data recovery circuit,
wherein the first clock and data recovery circuit controls the phase of the recovery clock with either the second phase control signal generated by the second clock and data recovery circuit or the first phase control signal generated by the first clock and data recovery circuit.

2. The semiconductor system according to claim 1, wherein data inversions in the second serial data occur more frequently than in the first serial data.

3. The semiconductor system according to claim 2, wherein the second serial data is a clock signal.

4. The semiconductor system according to claim 1, with a first clock and data recovery circuit comprising:
a clock control circuit for controlling the phase of the recovery clock,
a phase detector for comparing the phase of the recovery clock with the first serial data,
an averaging circuit for averaging the phase comparison results from the phase detector,
a compare circuit for comparing the averaged phase comparison results with a threshold level and generating a first phase control signal,
a select circuit for selecting either the first phase control signal or the second phase control signal,
wherein the clock control circuit controls the phase of the recovery clock with a phase control signal output from the select circuit.

5. The semiconductor system according to claim 1, wherein the phase control signal is one of an UP signal showing the recovery clock phase lags the received data phase; a DOWN signal showing the phase of the recovery clock leads the received data phase; or a FIX signal showing that the deviation between the recovery clock phase and the received data phase is within a specified range.

6. The semiconductor system according to claim 4, wherein the averaging circuit comprises a first two-way shift register for changing the value being held according to the phase comparison results from the phase detector, and
a second two-way shift register for changing the retained value according to the overflow signal from the first two-way shift register.

7. A serial to parallel converter method comprising:
receiving first serial data from a first transmission path;
receiving second serial data from a second transmission path;
generating a second phase control signal based on the phase differential between the second serial data and the clock for converting the second serial data to parallel data; and
controlling the phase of the clock for converting the first serial data to parallel data with the second phase control signal.

8. The serial to parallel converter method according to claim 7, comprising:
generating a first phase control signal based on the phase differential between the first serial data and the clock for converting the first serial data to parallel data;
receiving the control signal;
controlling the phase of the clock for converting the first serial data to parallel data with the first phase control signal, when the control signal is in a first state; and
controlling the phase of the clock for converting the first serial data to parallel data with the second phase control signal, when the control signal is in a second state.

9. The serial to parallel converter method according to claim 8, wherein the control signal becomes the first state in the training period.

10. The semiconductor system according to claim 8, wherein data inversions in the second serial data occur more frequently than in the first serial data.

11. The semiconductor system according to claim 10, wherein the second serial data is a clock signal.
